(19) United States
(12) Patent Application Publication
(10) Pub. No.: US 2026/0020350 A1
(43) Pub. Date: Jan. 15, 2026

(54) ESD PROTECTION DEVICE WITH ROBUST TRIGGER ELEMENTS

(71) Applicant: Infineon Technologies AG, Neubiberg (DE)

(72) Inventors: Vadim Valentinovic Vendt, Ottobrunn (DE); Egle Tylaite, München (DE); Joost Adriaan Willemen, München (DE)

(21) Appl. No.: 19/266,369

(22) Filed: Jul. 11, 2025

Related U.S. Application Data
(60) Provisional application No. 63/670,408, filed on Jul. 12, 2024.

(51) Int. Cl. H10D 89/60; H10D 8/20; H10D 62/10; H10D 62/83; H10D 64/23

(52) U.S. Cl. CPC H10D 89/611; H10D 8/20; H10D 62/126; H10D 62/83; H10D 64/23

(57) ABSTRACT

A semiconductor device includes a first row of doped wells including first conductivity type wells arranged alternatingly with second conductivity type wells in a semiconductor body, a first electrically conductive contact formed on the semiconductor body electrically connected with one of the first conductivity type wells, a second electrically conductive contact formed on the semiconductor body electrically connected with one of the second conductivity type wells, and a trigger region that including a trigger element that is configured to generate a trigger current that induces direct current flow between the first and second conductivity type wells, wherein the trigger region comprises one or more current spreading interfaces that are configured to reduce a current density of the trigger current as it transitions between at least one of the first and second electrically conductive contacts and the semiconductor body.

### TECHNICAL FIELD

The instant application relates to semiconductor devices, and more particularly to electrostatic discharge protection devices.

### BACKGROUND

Components such as transistors, diodes, resistors, electro-optical devices, precision film resistors and a variety of integrated circuits are all sensitive to electrostatic discharge (ESD). As electronics manufacturers drive to miniaturize devices and improve operating speeds, susceptibility of devices to ESD is increasing. For avoiding damage to integrated circuits or electronic devices by pulses during assembly or operation, ESD protection devices are connected between pins of an integrated circuit or between traces on a printed circuit board to prevent a malfunction or breakdown of circuits connected between the pins or traces by ESD current pulses. ESD protection devices are configured to be non-conductive at normal operational levels and become conductive in the presence of an overvoltage from an ESD event to divert damaging current from sensitive elements.

Multi-finger ESD protection devices include rows of doped wells, i.e., “fingers,” that alternate in conductivity type. This arrangement is used to form multiple ESD protection devices from sub-groups of the doped wells that conduct in parallel with one another. A multi-finger ESD protection device may include trigger devices that, in response to an ESD event, provide a trigger current that induces direct conduction between the doped wells of the device. It is desirable to create multi-finger ESD protection devices with robust trigger structures that can accommodate steep current transients.

### SUMMARY

Those skilled in the art will recognize additional features and advantages upon reading the following detailed description, and upon viewing the accompanying drawings.

According to an embodiment, a semiconductor device comprises a first row of doped wells formed in an upper surface of a semiconductor body, the first row comprising first conductivity type wells arranged alternatingly with second conductivity type wells in a first direction of the semiconductor body, a first electrically conductive contact formed on the upper surface of the semiconductor body and electrically connected with one of the first conductivity type wells, a second electrically conductive contact formed on the upper surface of the semiconductor body and electrically connected with one of the second conductivity type wells, and a trigger region arranged between the first and second electrically conductive contacts, wherein the trigger region comprises a trigger element that is configured to generate a trigger current that flows between the first and second electrically conductive contacts and thereby induces direct current flow between the first and second conductivity type wells electrically connected with the first and second electrically conductive contacts, respectively, and wherein the trigger region comprises one or more current spreading interfaces that are configured to reduce a current density of the trigger current as it transitions between at least one of the first and second electrically conductive contacts and the semiconductor body.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a plan-view layout of an ESD protection device, according to an embodiment.

FIG. 2, which includes FIGS. 2A and 2B, illustrates cross-sectional views of the ESD protection device of FIG. 1, according to an embodiment. FIG. 2A illustrates a cross-sectional view of the ESD protection device along a plane that is outside a trigger region and FIG. 2B illustrates a cross-sectional view of the ESD protection device along a plane that intersects a trigger region.

FIG. 3, which includes FIGS. 3A and 3B, schematically illustrates a plan-view layout of a trigger region of an ESD protection device, according to an embodiment. FIG. 3A shows a complete view of trigger current flowing through a trigger region and FIG. 3B illustrates a current crowding that occurs at a surface of the semiconductor body in the trigger region.

FIG. 4 illustrates a close-up view of an interface between a trigger region and a conductive runner, according to an embodiment.

FIG. 5 illustrates a plan-view layout of an ESD protection device wherein a trigger region is provided outside of an active area that comprises doped wells of the ESD protection device, according to an embodiment.

### DETAILED DESCRIPTION

Embodiments of an ESD protection device are disclosed herein. The ESD protection device is a multi-finger ESD protection device comprising a row of doped wells with p-type wells and n-type wells arranged alternatingly with one another. The ESD protection device comprises trigger devices that are designed to place the ESD protection device in conduction mode by inducing a current between the p-type wells and n-type wells. These trigger devices can experience rapid current transients during an ESD event. These rapid current transients can cause significant ohmic heating of the electrically conductive contacts, which can melt the underlying semiconductor material and cause damage and even device failure. Advantageously, the embodiments of the ESD protection device disclosed herein include trigger regions that are designed to provide enhanced robustness against rapid current transients. The trigger region design includes current spreading interfaces that disperse the trigger current as it enters or exits the electrically conductive contact structure on the surface of the semiconductor body, thereby reducing the local current density at the conductor-semiconductor interface and consequently mitigating the possibility of melting of the semiconductor material.

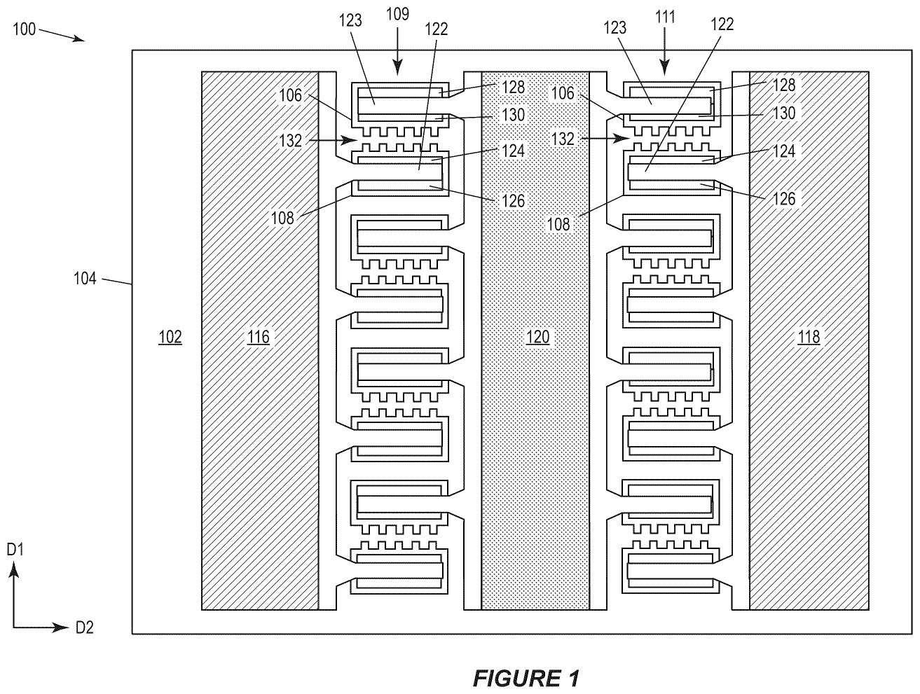

Referring to FIG. 1, an ESD protection device 100 is depicted, according to an embodiment. The ESD protection device 100 is formed in an upper surface 102 of a semiconductor body 104. The semiconductor body 104 may include or consist of a semiconductor material from group IV elemental semiconductors, IV-IV compound semiconductor material, III-V compound semiconductor material, or II-VI compound semiconductor material. Examples of semiconductor materials from the group IV elemental semiconductors include, inter alia, silicon (Si) and germanium (Ge). Examples of IV-IV compound semiconductor materials include, inter alia, silicon carbide (SiC) and silicon germanium (SiGe). Examples of III-V compound semiconductor material include, inter alia, gallium arsenide (GaAs), gallium nitride (GaN), gallium phosphide (GaP), indium phosphide (InP), indium gallium nitride (InGaN) and indium gallium arsenide (InGaAs). Examples of II-VI compound semiconductor materials include, inter alia, cadmium telluride (CdTe), mercury-cadmium-telluride (CdHgTe), and cadmium magnesium telluride (CdMgTe). The semiconductor body 104 may include other active devices, e.g., transistors and in particular power switching devices, e.g., MOSFETs, IGBTs, HEMTs, etc., in addition to the ESD protection device 100. Alternatively, the ESD protection device 100 may be implemented as a discrete device that is configured to protect an external element though external connections, e.g., bond wire connections, PCB connections, etc.

The ESD protection device 100 comprises a plurality of p-type wells 106 and n-type wells 108 formed in the upper surface 102 of the semiconductor body 104. The p-type wells 106 and n-type wells 108 are arranged in rows, wherein the p-type wells 106 and the n-type wells 108 alternate with one another. As shown, the ESD protection device 100 comprises a first row 109 of the p-type wells 106 and n-type wells 108 on the left side of the figure and a second row 111 of the p-type wells 106 and n-type wells 108 on the right side of the figure. In these rows, the p-type wells 106 and the n-type wells 108 alternate with one another along a first direction D1. According to an embodiment, the ESD protection device 100 is configured such that a unit cell comprising, e.g., one of the p-type wells 106 and half of two of the n-type wells 108 on either side of the p-type well 106 (or vice-versa) has a fixed width, thus allowing for the provision of multiple unit cells being arranged next to one another in a regular spacing. For example, each of these unit cells may have a regular width of between 1.0 μm and 15.0 μm.

The ESD protection device 100 comprises first and second shallow doped zones 124, 126 disposed within each of the n-type wells 108. The first and second shallow doped zones 124, 126 have an opposite conductivity type from one another. The first shallow doped zones 124 are p-type regions that form a p-n junction with the subjacent n-type wells 108 and the second shallow doped zones 126 are n-type regions that are more highly doped than the underlying n-type wells 108. Correspondingly, the ESD protection device 100 comprises third and fourth shallow doped zones 128, 130 disposed within each of the p-type wells 106. The third and fourth shallow doped zones 128, 130 have an opposite conductivity type from one another. The third shallow doped zones 128 are p-type regions that are more highly doped than the underlying p-type wells 106. The fourth shallow doped zones 130 are n-type regions that form a p-n junction with the subjacent p-type wells 106.

According to an embodiment, the semiconductor body 104 has a background dopant concentration of no greater than 10¹⁵ dopant atoms/cm³ and more typically in the range of 10¹² dopant atoms/cm³ to 10¹⁴ dopant atoms/cm³. The background dopant concentration of the semiconductor body 104 can be a net p-type or a net n-type concentration and may be selected to be opposite in conductivity type as the wells that are connected to the first and second contact pads 116, 118. The p-type wells 106 and the n-type wells 108 have a higher net dopant concentration than the background dopant concentration of the semiconductor body 104. For example, the n-type wells 108 may have a net n-type dopant concentration of at least 10¹⁵ dopant atoms/cm³ and more typically in the range of 10¹⁷ dopant atoms/cm³. Likewise, the p-type wells 106 may have a net p-type dopant concentration of at least 10¹⁵ dopant atoms/cm³ and more typically in the range of 10¹⁷ dopant atoms/cm³. The first second, third and fourth shallow doped zones 124, 126, 128, 130 have a higher net dopant concentration than the underlying dopant concentration of the n-type wells 108 or the p-type wells 106 that these zones are formed within. For example, the first and third shallow doped zones 124, 128 may have a net p-type dopant concentration of at least 10¹⁹ dopant atoms/cm³ and more typically in the range of 10¹⁹ dopant atoms/cm³ to 10²¹ dopant atoms/cm³ and the second and fourth shallow doped zones 126, 130 may have a net n-type dopant concentration of at least 10¹⁹ dopant atoms/cm³ and more typically in the range of 10¹⁹ dopant atoms/cm³ to 10²¹ dopant atoms/cm³.

The above-described doped regions of the ESD protection device 100 may be formed using masked implantation techniques. According to an embodiment, the p-type wells 106 are formed by a first implantation process that implants p-type dopants in the semiconductor body 104 and the n-type wells 108 are formed by a second implantation process that implants n-type dopants into the semiconductor body 104. For example, in the case of a semiconductor body 104 formed of silicon, the first implantation process may comprise implanting any one or more of: B, BF, BF₂, Al, etc. into the semiconductor body 104, and the second implantation process may comprise implanting any one or more of: P, As, Bi, etc. into the semiconductor body 104. In this context, the terms “first” and “second” implantation processes do not denote a particular order. The first, second, third and fourth shallow doped zones 124, 126, 128, 130 may be formed by further implantation processes that are performed after the first and second implantation processes as described above. For example, the first and third shallow doped zones 124, 128 may be formed by a third implantation process that implants p-type dopants into the semiconductor body 104 and the second and fourth shallow doped zones 126, 130 may be formed by a fourth implantation process that implants n-type dopants into the semiconductor body 104. In this context, the terms “third” and “fourth” implantation process do not denote a particular order. The implanted dopant atoms may be activated by annealing steps, which may be performed concurrently after individual implantation processes or after all implantation processes are performed.

The ESD protection device 100 comprises a first contact pad 116, a second contact pad 118 and a central interconnect structure 120. The first contact pad 116 is electrically connected to the n-type wells 108 in the first row 109 via a group of first conductive runners 122 that extend directly over these n-type wells 108. The second contact pad 118 is electrically connected to the n-type wells 108 in the second row 111 via another group of first conductive runners 122 that extend directly over these n-type wells 108. The central interconnect structure 120 is electrically connected to the p-type wells 106 in the first row 109 and the p-type wells 106 in the second row 111 by groups of second conductive runners 123 that extend directly over these p-type wells 106. The first contact pad 116, the second contact pad 118 and the central interconnect structure 120 may each be formed from an electrically conductive material, e.g., copper, aluminum, nickel, and alloys thereof. The first and second conductive runners 122, 123 may likewise be formed from an electrically conductive material, e.g., copper, aluminum, nickel, and alloys thereof, or highly doped polysilicon.

The working principle of the ESD protection device 100 is as follows. The ESD protection device 100 is a lateral device, meaning that it is configured to conduct or block a current flowing parallel to the upper surface 102 of the semiconductor body 104. In a conduction mode of the ESD protection device 100, current flows between the first contact pad 116 and the second contact pad 118. A grouping of the n-type wells 108 in the first row 109, the p-type wells 106 in the first row 109, the p-type wells 106 in the second row 111 and the n-type wells 108 in the second row 111 collectively form an NPNP structure between the first contact pad 116 and the second contact pad 118. At one voltage polarity one of the first and second rows 109, 111 operates in SCR mode, whereas the other one of the first and second rows 109 operates as a forward biased p-i-n diode. At the opposite voltage polarity, the first and second rows 109, 111 operating in SCR mode and p-i-n diode mode switch. As result of having these two devices arranged in an anti-series configuration, the ESD protection device 100 is symmetric and bidirectional as between the first contact pad 116 and the second contact pad 118. Stated another way, the ESD protection device 100 is a bidirectional device with 2 identical device structures of reversed orientation connected in series with one another. The ESD protection device 100 comprises trigger regions 132 in between one of the p-type wells 106 and one of the n-type wells 108. These trigger regions 132 operate as avalanche diodes that become conductive when an avalanche breakdown condition is reached. Once the device is in the conduction state, a three-dimensional current flows between the n-type wells 108 and the p-type wells 106 within the semiconductor body 104. This concept can be used to form a low-ohmic current path that shunts a sudden and large current, e.g., from an ESD event, away from another device that is connected to the ESD protection device 100.

The ESD protection device 100 comprises trigger regions 132 in between the p-type wells 106 and one of the n-type wells 108 in each of the first and second rows 109, 111. The trigger regions 132 are configured to generate a trigger current that initiates conduction between one of the p-type wells 106 and one of the n-type wells 108. Once the device is in the conduction state, a three-dimensional current flows between the n-type wells 108 and the p-type wells 106 within the semiconductor body 104.

The ESD protection device 100 may optionally comprise electrical isolation regions formed in the semiconductor body 104 around the n-type wells 108 and the p-type wells 106. For simplicity sake, these electrical isolation regions have been omitted from FIG. 1. These electrical isolation regions may lead to improved device performance by lowering total device capacitance. An example of an ESD protection device with electrical isolation regions is described in U.S. Pat. No. 11,776,996 to Tylaite, the content of which is described by reference herein in its entirety. In an embodiment, the ESD protection device 100 comprises the isolating regions, and the electrical isolation regions are configured such that the isolating area surrounding the p-type wells is equal to the isolating area surrounding the n-type wells. In another embodiment the ESD protection device 100 comprises the isolating regions, and the electrical isolation regions are configured such that the isolating area surrounding the p-type wells is greater than the isolating area surrounding the n-type wells, e.g., as described in the above-mentioned Tylaite reference.

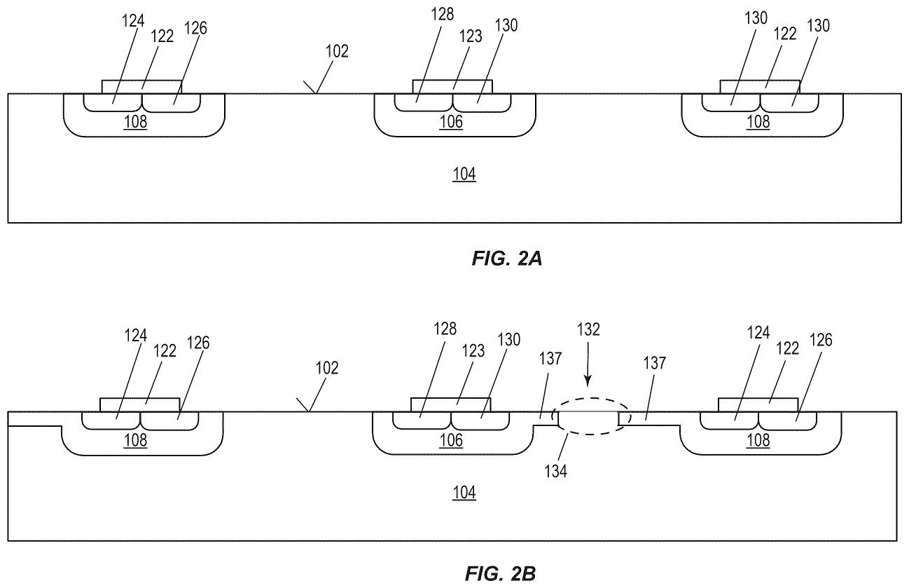

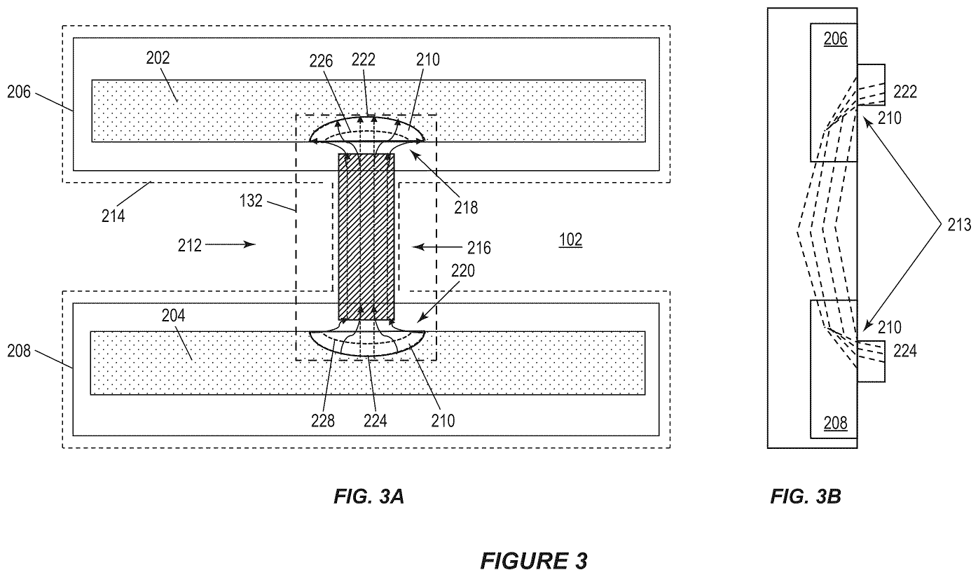

Referring to FIG. 2, the ESD protection device 100 from FIG. 1 is shown from a cross-sectional perspective. FIG. 2A shows the ESD protection device 100 along a cross-section that extends in the first direction D1 and is between one of the trigger regions 132. FIG. 2B shows the ESD protection device 100 along a cross-section that extends in the first direction D1 and intersects one of the trigger regions 132. In this example, the trigger regions 132 comprise avalanche diode structures that are configured to generate the trigger current. As shown in FIG. 2B, the trigger regions 132 include a low-doped section 134 of the semiconductor body 104 in between one of the p-type wells 106 and one of the n-type wells 108. The breakdown voltage VBR of the avalanche diode structure that triggers conduction of the ESD protection device 100 is determined by the width of the low-doped section 134 of the semiconductor body 104 in between the p-type wells 106 and the n-type wells 108. In the depicted embodiment, the low-doped section 134 of the semiconductor body 104 in the trigger regions 132 correspond to regions in which the boundaries of the p-type wells 106 and the n-type wells 108 are brought closer to one another, relative to the distance between these wells outside of the trigger regions 132. As shown, both the p-type wells 106 and the n-type wells 108 each comprise an extension region 137 that extends towards an adjacent doped well, thereby locally reducing the distance between the p-type wells 106 and the n-type wells 108 to define the width of the low-doped section 134. In this way, an avalanche breakdown occurs locally where the trigger regions 132 are formed. Separately or in combination, the trigger regions 132 may comprise paths of low-doped semiconductor material interposed between regions of electrical isolation material, e.g., as shown in FIG. 3 below. In general, the semiconductor material in the low-doped sections 134 can have any dopant concentration that is lower than that of the p-type wells 106 and the n-type wells 108. As shown, the low-doped sections 134 may correspond to a region of intrinsic, i.e., unintentionally doped, material from the semiconductor body 104. Other trigger configurations are possible. For example, the trigger regions 132 may correspond to regions wherein the p-type wells 106 and the n-type wells 108 locally adjoin one another. In another example, the trigger regions 132 may correspond to highly doped regions in between the p-type wells 106 and the n-type wells 108.

During an ESD event, the trigger devices of the ESD protection device 100 are required to accommodate large current transients. For example, the ESD protection device 100 may experience a current transient of at least 50 A (Amperes), 60 A, 75 A, 100 A, or more within rise times of 250 ps (picoseconds), 200 ps, 150 ps, 100 ps or less. This can cause the electrically conductive contact structures formed on the semiconductor body 104, i.e., the first and second conductive runners 122, 123 in the depicted embodiment, to experience substantial joule heating, which in turn can cause crystalline damage to the underlying semiconductor material that interfaces with these contacts. One solution to this problem is to increase the layout area of the trigger regions 132 and associated conductive runners 122, 123 that accommodate the large current transients. However, doing so involves making unwanted tradeoffs, such as reduced space efficiency and increased device capacitance. The embodiments to be described below advantageously increase robustness against large current transients without making these unwanted tradeoffs with respect to space efficiency device capacitance. In these embodiments, the trigger regions 132 comprise current spreading interfaces arranged between the trigger devices and the electrically conductive contacts that experience the current transients. These current spreading interfaces comprise geometric features that cause the trigger current to be distributed over a greater area as it flows into and out of the electrically conductive contacts. As a result, the device can accommodate larger current transients before the semiconductor material is overheated.

Referring to FIG. 3A, a trigger region 132 of an ESD protection device 100 is arranged between a first electrically conductive contact 202 and a second electrically conductive contact 204. The first electrically conductive contact 202 is formed on the upper surface 102 of the semiconductor body 104 and is electrically connected with a first conductivity type well 206. The second electrically conductive contact 204 is formed on the upper surface 102 of the semiconductor body 104 and is electrically connected with a second conductivity type well 208. The first electrically conductive contact 202 and the second electrically conductive contact 204 each comprise an electrically conductive material, e.g., copper, aluminum, nickel, and alloys thereof, or highly doped polysilicon, that interfaces with the upper surface 102 of the semiconductor body 104. The first conductivity type well 206 may correspond to one of the p-type wells 106 from the first or second rows 109, 111 in the ESD protection device 100 of FIG. 1, the second conductivity type well 208 may correspond to one of the n-type wells 108 from the first or second rows 109, 111 in the ESD protection device 100 of FIG. 1, and the first and second electrically conductive contacts 202, 204 may correspond to the first and second conductive runners 122, 123 formed thereon. The ESD protection device 100 comprises highly doped ohmic contact regions 210 that extend to the upper surface 102 of the semiconductor body 104 and form an ohmic connection interface with the first and second electrically conductive contacts 202, 204. The highly doped ohmic contact regions 210 facilitate a low-ohmic i.e., non-rectifying connection between the semiconductor material and the first and second electrically conductive contacts 202, 204. The highly doped ohmic contact regions 210 may have a dopant concentration of at least 10¹⁹ dopant atoms/cm³ and more typically in the range of 10¹⁹ dopant atoms/cm³ to 10²¹. Depending on the device configuration, the highly doped ohmic contact regions 210 may have either the same or opposite conductivity type as the underlying doped wells. In an embodiment, the highly doped ohmic contact region 210 underneath the first electrically conductive contact 202 corresponds to the fourth shallow doped zone 130 and the highly doped ohmic contact region 210 underneath the second electrically conductive contact 204 corresponds to the first shallow doped zone 124 in the ESD protection device 100 of FIG. 1.

The trigger region 132 comprises a trigger element 212 that is configured to generate a trigger current that flows from the second electrically conductive contact 204 to the first electrically conductive contact 202 and thereby induces direct current flow between the first conductivity type well 206 and the second conductivity type well 208 electrically connected with the first and second electrically conductive contacts 202, 204, respectively. In an embodiment, the trigger element 212 is an avalanche diode formed by a low-doped section 134 of the semiconductor body 104 arranged between one of the first conductivity type wells 206 and one of the second conductivity type wells 208, as described above. Although the depicted trigger region 132 shows only one trigger element 212 arranged between the first and second electrically conductive contacts 202, 204, it shall be understood that multiple trigger elements 212 may be provided between the first and second electrically conductive contacts 202, 204, e.g., in a similar manner as shown in FIG. 1, and the current spreading interfaces shown in FIG. 3 and to be described below may be provided for each of these trigger elements 212. In the depicted embodiment of FIG. 3, the trigger element 212 is formed by a path of low-doped semiconductor material interposed between regions of electrical isolation material 214. Optionally, trigger region 132 may comprise the extension regions 137 (not seen in FIG. 3) as described above with reference to FIG. 2.

The trigger region 132 comprises a bridge region 216 disposed between the first and second electrically conductive contacts 202, 204. The bridge region 216 forms a constricted conduction path between the first conductivity type well 206 and the second conductivity type well 208. FIG. 3 shows a trigger current that flows between the first and second electrically conductive contacts 202, 204 during an ESD event in which the trigger element 212 becomes conductive. This trigger current must flow through the bridge region 216. The bridge region 216 may comprise the low-doped section 134 that forms the intrinsic region of an avalanche diode and the extension regions 137 (if present) of the first conductivity type well 206 and the second conductivity type well 208.

The trigger region 132 additionally comprises first and second transition regions 218, 220 between the bridge region 216 and the first and second electrically conductive contacts 202, 204. The first and second transition regions 218, 220 are regions of semiconductor material that the trigger current flows through as it exits or enters the first and second electrically conductive contacts 202, 204. The first and second transition regions 218, 220 may comprise parts of the first and second conductivity type wells 208, respectively, as well as parts of the highly doped ohmic contact regions 210 within these regions that extend up to the conductor-semiconductor interface between the first and second electrically conductive contacts 202, 204 and the semiconductor body 104.

The trigger region 132 comprises current spreading interfaces that are configured to reduce the current density of the trigger current as it transitions between the semiconductor body 104 and the first and second electrically conductive contacts 202, 204. As shown, the current spreading interfaces are disposed within the first and second transition regions 218, 220. The current spreading interfaces refer to interfaces between regions of different electrical conductivity. The current spreading interfaces may include the interfaces between the first and second electrically conductive contacts 202, 204 and the semiconductor body 104, as well as the interfaces between the highly doped ohmic contact regions 210 and the adjacent doped regions with a lower dopant concentration. The current spreading interfaces cause the trigger current to gradually taper inward as it exits the second electrically conductive contact 204 and flows towards the bridge region 216 and likewise cause the trigger current to gradually taper outward as it exits the bridge region 216 and flows into the first electrically conductive contact 202. As a result, the current density of the trigger current at the conductor-semiconductor interface is lower in comparison to the bridge region 216.

In the depicted embodiment, the current spreading interfaces comprise a first indentation 222 in a side face of the first electrically conductive contact 202 that faces the bridge region 216 and a second indentation 224 in a side face of the second electrically conductive contact 204 that faces the bridge region 216. The first and second indentations 222, 224 refer to regions in which the electrically conductive material is pulled back to increase the length of the trigger current between the bridge region 216 and the electrically conductive contacts to increase the effective length of the side face that intersects the trigger current. As shown, the first and second indentations 222, 224 may be formed to be wider than bridge region 216 so as to eliminate short distance paths between the side faces of the first conductive runner and the corners of the bridge region 216.

In an embodiment of making the ESD protection device 100, the size of the first and second indentations 222, 224 is selected for optimal or near-optimal trigger robustness. As the size of the first and second indentations 222, 224 is increased, the effective contact area of the first and second electrically conductive contacts 202, 204 is correspondingly decreased. At a certain point, the detrimental impact on contact resistance due to reduced contact area outweighs the beneficial impact on current crowding. In one example of a technique for selecting optimal or near-optimal trigger robustness, different indentation depths in the first and second electrically conductive contacts 202, 204 are tested against a stress pulse condition. The indentation depth refers to the maximum deflection in the side face of the respective conductive runner away from the bridge region 216. The stress pulse condition represents a worst-case transient stress that may flow through the trigger element 212 during an ESD event. Using a stress pulse condition of a pulse width of 5 ns, a risetime of 100 ps and a current amplitude change from 0 to 60 A, and using concave shaped indentations, indentation depths of between 0.2 μm and 1.0 μm, and more particularly between 0.3 μm and 0.5 μm, and more particularly between 0.35 μm and between 0.45 μm have been identified as capturing an optimal or near optimal tradeoff that maximizes contact robustness in one particular layout and material configuration. Of course, these values may differ, depending on a variety of factors. According to the above-described technique, an optimal or near optimal indentation depth may be identified for given stress pulse conditions, indentation shape, conductive contact size, and material configuration.

According to the depicted embodiment, the first indentation 222 and the second indentation 224 each form a concave shape, i.e., a curved shape in an otherwise linear side face. More generally, the first indentation 222 and/or the second indentation 224 may have a variety of different geometries that serve to taper the trigger current and/or increase the effective length of the current interface between the electrically conductive contacts and the semiconductor material, examples of which include different curved shapes, e.g., ellipsoids, partial circles, rectangular shapes including squares and non-symmetric rectangles, other polygonal geometries such as half-hexagons, W-shapes, V-shapes, U-shapes, and any other types of any non-linearities in the side faces of the electrically conductive contacts.

In the depicted embodiment, the current spreading interfaces additionally comprise a first pull-back 226 in a sidewall of the highly doped ohmic contact region 210 that is underneath the first electrically conductive contact 202 and faces the bridge region 216, and a second pull-back 228 in a sidewall of the highly doped ohmic contact region 210 that is underneath the second electrically conductive contact 204 and faces the bridge region 216. The first and second pull-backs 226, 228 refer to modifications in the outer borders of the highly doped ohmic contact regions 210 to increase the length of the current path from the bridge regions 216 to the highly doped ohmic contact regions 210 and modify the directional flow of the trigger current. The pull-backs assist in the tapering of the trigger current towards the sidewalls of the first and second indentations 222, 224. According to an embodiment, the geometry of the first and second pull-backs 226, 228 mimics the geometry of the first and second indentations 222, 224 to which they are associated with. That is, the first and second pull-backs 226, 228 form the same general shape as the first and second indentations 222, 224. This ensures more uniform distribution of the trigger current along the length of the side faces of the first and second electrically conductive contacts 202, 204 within the indentations. FIG. 3 illustrates one example of an embodiment wherein the first and second pull-backs 226, 228 mimic the concave shaped geometry of the first and second indentations 222, 224, respectively. As shown, the first and second pull-backs 226, 228 may have the same concave shape but less depth as the first and second indentations 222, 224.

Referring to FIG. 3B, an illustration of the trigger current is shown between the first conductivity type well 206 and the second conductivity type well 208 with particular emphasis on the effect at the upper surface 102 of the semiconductor body 104. While the trigger current flows three dimensionally within the semiconductor body 104, a current-crowding effect occurs as the trigger current flows into and out of the highly doped ohmic contact regions 210 as described herein. As highlighted in FIG. 3B, the trigger current bends around acute inflection points 213 wherein the highly doped ohmic contact regions 210 interface with the first conductivity type well 206 and the second conductivity type well 208. The geometric configurations of the current spreading interfaces decrease the severity of the acute inflection points 213 and consequently relax the current density at these locations.

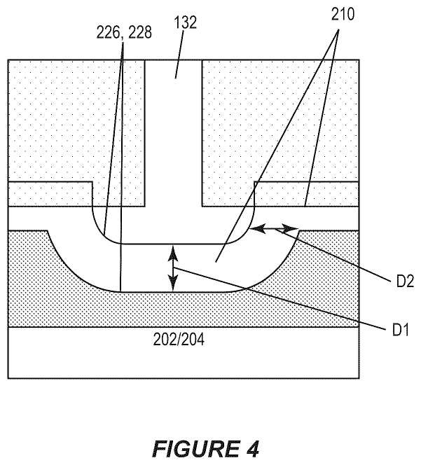

Referring to FIG. 4, an interface between a trigger region 132 of an ESD protection device 100 and either one of the first or second conductive contact 202 is shown, according to another embodiment. In this case, the highly doped ohmic contact regions 210 comprise the pull-backs 226, 228, as described above. These pull-backs 226, 228 have a first pull-back distance D1 and a second pull-back distance D2. In an embodiment, the first pull-back distance D1 is the same as the second pull-back distance D2. In another embodiment, the first pull-back distance D1 is different from the second pull-back distance D2.

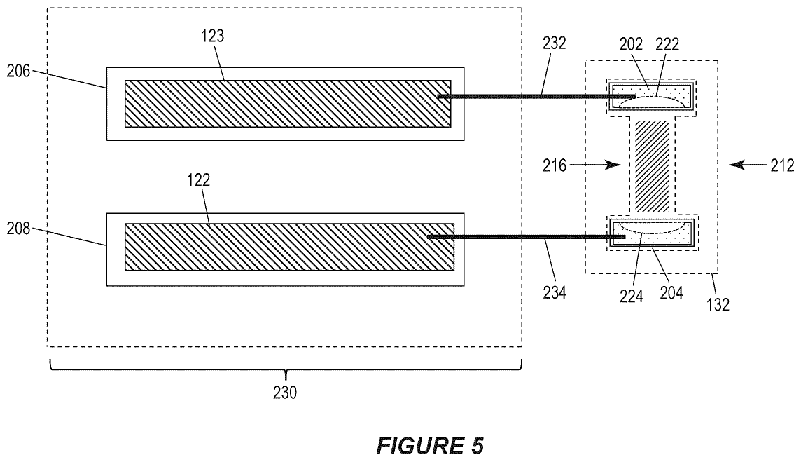

Referring to FIG. 5, an ESD protection device 100 having a trigger region 132 with current spreading interfaces is depicted, according to another embodiment. In this case, the trigger region 132 is provided outside of an active area 230 that comprises the first and second rows 109, 111 of doped wells. Thus, the trigger element 212 is not formed using the same doped wells which form the rectifier device. The trigger region 132 comprises a first electrically conductive contact 202 that is electrically connected to a first conductive runner 122 formed directly over one of the first conductivity type wells 206 by a first electrical interconnect 232, and a second electrically conductive contact 204 that is electrically connected to a second conductive runner 123 formed directly over one of the second conductivity type wells 208 by a second electrical interconnect 234. The first and second electrical interconnects 232, 234 may be provided in metal interconnect tracks formed form copper, aluminum, etc. In the embodiment of FIG. 4, the trigger element 212 may be configured as an avalanche diode in a similar manner described above. Alternatively, the trigger element 212 may comprise any type of device that can be actively controlled to generate a trigger current, e.g., various types of p-n diodes, transistors such as MOSFETs and BJTs, including NPN and PNP devices. The trigger region 132 of the ESD protection device 100 of FIG. 4 may comprise the current spreading interfaces according to any of the embodiments described herein. For example, as shown, the trigger region 132 of the ESD protection device 100 of FIG. 4 comprises the first and second indentations 222, 224 in the first and second electrically conductive contacts 202, 204. Accordingly, a beneficial impact on current dispersion at the conductor-semiconductor interface is realized.

In addition to the depicted embodiments, embodiments of an ESD protection device 100 may include any type of current spreading interface provided on one or both sides of the trigger element 212. For example, an embodiment of an ESD protection device 100 may comprise a current spreading interface provided within only one of the first and second transition regions 218, 220. In another example, an embodiment of an ESD protection device 100 may comprise a first current spreading interface within the first transition region and second current spreading interface that is different from the first current spreading interface within the second transition region. In all of these embodiments, the current spreading interfaces can include any combination of the indentations or non-linearities in the first and/or second electrically conductive contacts 202, 204 and the pull-backs of the highly doped ohmic contact regions 210 as described herein.

In addition to the described ESD protection device 100 described above, the concepts described herein, and in particular the provision of a current spreading interface within a trigger region, may be incorporated into a variety of different ESD protection devices. These ESD protection devices 100 include unidirectional devices, and p-i-n diodes, for example. In one particular example, the second and fourth shallow doped zones 126, 130 may be omitted from the device.

Although the present disclosure is not so limited, the following numbered examples demonstrate one or more aspects of the disclosure.

Example 1. A semiconductor device, comprising: a first row of doped wells formed in an upper surface of a semiconductor body, the first row comprising first conductivity type wells arranged alternatingly with second conductivity type wells in a first direction of the semiconductor body; a first electrically conductive contact formed on the upper surface of the semiconductor body and electrically connected with one of the first conductivity type wells; a second electrically conductive contact formed on the upper surface of the semiconductor body and electrically connected with one of the second conductivity type wells; and a trigger region arranged between the first and second electrically conductive contacts, wherein the trigger region comprises a trigger element that is configured to generate a trigger current that flows between the first and second electrically conductive contacts and thereby induces direct current flow between the first and second conductivity type wells electrically connected with the first and second electrically conductive contacts, respectively, and wherein the trigger region comprises one or more current spreading interfaces that are configured to reduce a current density of the trigger current as it transitions between at least one of the first and second electrically conductive contacts and the semiconductor body.

Example 2. The semiconductor device of example 1, wherein the trigger region comprises a bridge region disposed between the first and second electrically conductive contacts and first and second transition regions between the bridge region and the first and second electrically conductive contacts, respectively, and wherein the one or more current spreading interfaces that are configured to taper the trigger current within one or both of the first and second transition regions.

Example 3. The semiconductor device of example 2, wherein the one or more current spreading interfaces comprise a first indentation in a side face of the first electrically conductive contact that faces the bridge region.

Example 4. The semiconductor device of example 3, wherein the first indentation has a concave shape.

Example 5. The semiconductor device of example 3, wherein a depth of the first indentation is between 0.2 μm and 1.0 μm.

Example 6. The semiconductor device of example 3, wherein the one or more current spreading interfaces comprise a second indentation in a side face of the second electrically conductive contact that faces the bridge region.

Example 7. The semiconductor device of example 6, wherein the first and second indentations each have a concave shape.

Example 8. The semiconductor device of example 3, wherein the semiconductor device comprises a highly doped ohmic contact region that extends to the upper surface of the semiconductor body and forms an ohmic connection interface with the first electrically conductive contact, and wherein the one or more current spreading interfaces further comprise a first pull-back in a sidewall of the highly doped ohmic contact region that faces the bridge region.

Example 9. The semiconductor device of example 8, wherein a geometry of the first pull-back mimics a geometry of the first indentation.

Example 10. The semiconductor device of example 9, wherein the first pull-back and the first indentation each have a concave shape.

Example 11. The semiconductor device of example 10, wherein a depth of the first indentation is greater than a depth of the first pull-back.

Example 12. The semiconductor device of example 2, wherein the first electrically conductive contact is a first conductive runner formed directly over one of the first conductivity type wells from the first row, and wherein the second electrically conductive contact is a second conductive runner formed directly over one of the second conductivity type wells from the first row.

Example 13. The semiconductor device of example 12, wherein the bridge region is a low-doped region of the semiconductor body arranged between one of the first conductivity type wells from the first row and one of the second conductivity type wells from the first row, and wherein the trigger device is configured to generate the trigger current via avalanche breakdown within the low-doped region.

Example 14. The semiconductor device of example 2, wherein the first and second electrically conductive contacts are each formed outside of an active area that comprises the first row of doped wells, wherein the first electrically conductive contact is electrically connected to a first conductive runner formed directly over one of the first conductivity type wells by a first electrical interconnect, and wherein the second electrically conductive contact is electrically connected to a second conductive runner formed directly over one of the second conductivity type wells by a second electrical interconnect.

Example 15. The semiconductor device of example 1, wherein the semiconductor device is configured as a silicon-controlled rectifier device.

Example 16. The semiconductor device of example 1, further comprising: a second row of doped wells formed in the upper surface of the semiconductor body, the second row comprising first conductivity type wells arranged alternatingly with second conductivity type wells in the first direction of the semiconductor body; a third electrically conductive contact formed on the upper surface of the semiconductor body and electrically connected with one of the first conductivity type wells in the second row; a fourth electrically conductive contact formed on the upper surface of the semiconductor body and electrically connected with one of the second conductivity type wells in the second row; and a second trigger region arranged between the third and fourth electrically conductive contacts, wherein the second trigger region comprises a second trigger element that is configured to generate a second trigger current that flows between the third and fourth electrically conductive contacts and thereby induces direct current flow between the first conductivity type well and the first conductivity type well electrically connected with the third and fourth electrically conductive contacts, respectively, and wherein the second trigger region comprises one or more current spreading interfaces that are configured to reduce a current density of the second trigger current as it transitions between the semiconductor body and one or both of the third and fourth electrically conductive contacts.

Example 17. The semiconductor device of example 16, wherein the semiconductor device is configured as a bidirectional silicon-controlled rectifier device.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

Notably, modifications and other embodiments of the disclosed invention(s) will come to mind to one skilled in the art having the benefit of the teachings presented in the foregoing descriptions and the associated drawings. Therefore, it is to be understood that the invention(s) is/are not to be limited to the specific embodiments disclosed and that modifications and other embodiments are intended to be included within the scope of this disclosure. Although specific terms may be employed herein, they are used in a generic and descriptive sense only and not for purposes of limitation

With the above range of variations and applications in mind, it should be understood that the present invention is not limited by the foregoing description, nor is it limited by the accompanying drawings. Instead, the present invention is limited only by the following claims and their legal equivalents.

1. A semiconductor device, comprising:
a first row of doped wells formed in an upper surface of a semiconductor body, the first row comprising first conductivity type wells arranged alternatingly with second conductivity type wells in a first direction of the semiconductor body;
a first electrically conductive contact formed on the upper surface of the semiconductor body and electrically connected with one of the first conductivity type wells;
a second electrically conductive contact formed on the upper surface of the semiconductor body and electrically connected with one of the second conductivity type wells; and
a trigger region arranged between the first and second electrically conductive contacts,
wherein the trigger region comprises a trigger element that is configured to generate a trigger current that flows between the first and second electrically conductive contacts and thereby induces direct current flow between the first and second conductivity type wells electrically connected with the first and second electrically conductive contacts, respectively, and
wherein the trigger region comprises one or more current spreading interfaces that are configured to reduce a current density of the trigger current as it transitions between at least one of the first and second electrically conductive contacts and the semiconductor body.

2. The semiconductor device of claim 1, wherein the trigger region comprises a bridge region disposed between the first and second electrically conductive contacts and first and second transition regions between the bridge region and the first and second electrically conductive contacts, respectively, and wherein the one or more current spreading interfaces that are configured to taper the trigger current within one or both of the first and second transition regions.

3. The semiconductor device of claim 2, wherein the one or more current spreading interfaces comprise a first indentation in a side face of the first electrically conductive contact that faces the bridge region.

4. The semiconductor device of claim 3, wherein the first indentation has a concave shape.

5. The semiconductor device of claim 3, wherein a depth of the first indentation is between 0.2 μm and 1.0 μm.

6. The semiconductor device of claim 3, wherein the one or more current spreading interfaces comprise a second indentation in a side face of the second electrically conductive contact that faces the bridge region.

7. The semiconductor device of claim 6, wherein the first and second indentations each have a concave shape.

8. The semiconductor device of claim 3, wherein the semiconductor device comprises a highly doped ohmic contact region that extends to the upper surface of the semiconductor body and forms an ohmic connection interface with the first electrically conductive contact, and wherein the one or more current spreading interfaces further comprise a first pull-back in a sidewall of the electrically conductive contact that faces the bridge region.

9. The semiconductor device of claim 8, wherein a geometry of the first pull-back mimics a geometry of the first indentation.

10. The semiconductor device of claim 9, wherein the first pull-back and the first indentation each have a concave shape.

11. The semiconductor device of claim 10, wherein a depth of the first indentation is greater than a depth of the first pull-back.

12. The semiconductor device of claim 2, wherein the first electrically conductive contact is a first conductive runner formed directly over one of the first conductivity type wells from the first row, and wherein the second electrically conductive contact is a second conductive runner formed directly over one of the second conductivity type wells from the first row.

13. The semiconductor device of claim 12, wherein the bridge region is a low-doped region of the semiconductor body arranged between one of the first conductivity type wells from the first row and one of the second conductivity type wells from the first row, and wherein the trigger device is configured to generate the trigger current via avalanche breakdown within the low-doped region.

14. The semiconductor device of claim 2, wherein the first and second electrically conductive contacts are each formed outside of an active area that comprises the first row of doped wells, wherein the first electrically conductive contact is electrically connected to a first conductive runner formed directly over one of the first conductivity type wells by a first electrical interconnect, and wherein the second electrically conductive contact is electrically connected to a second conductive runner formed directly over one of the second conductivity type wells by a second electrical interconnect.

15. The semiconductor device of claim 1, wherein the semiconductor device is configured as a silicon-controlled rectifier device.

16. The semiconductor device of claim 1, further comprising:
a second row of doped wells formed in the upper surface of the semiconductor body, the second row comprising first conductivity type wells arranged alternatingly with second conductivity type wells in the first direction of the semiconductor body;
a third electrically conductive contact formed on the upper surface of the semiconductor body and electrically connected with one of the first conductivity type wells in the second row;
a fourth electrically conductive contact formed on the upper surface of the semiconductor body and electrically connected with one of the second conductivity type wells in the second row; and
a second trigger region arranged between the third and fourth electrically conductive contacts,
wherein the second trigger region comprises a second trigger element that is configured to generate a second trigger current that flows between the third and fourth electrically conductive contacts and thereby induces direct current flow between the first conductivity type well and the first conductivity type well electrically connected with the third and fourth electrically conductive contacts, respectively, and
wherein the second trigger region comprises one or more current of the current spreading interfaces that are configured to reduce a current density of the second trigger current as it transitions between the semiconductor body and one or both of the third and fourth electrically conductive contacts.

17. The semiconductor device of claim 16, wherein the semiconductor device is configured as a bidirectional silicon-controlled rectifier device.
